(19) United States
(12) Patent Application Publication
(10) Pub. No.: US 2015/0315012 A1
(43) Pub. Date: Nov. 5, 2015

(54) LIGHT DRIVEN LIQUID CRYSTAL ELASTOMER ACTUATOR

(71) Applicants: CNR - CONSIGLIO NAZIONALE DELLE RICERCHE, Roma (IT); ISTITUTO ITALIANO DI TECNOLOGIA, Genova (IT)

(72) Inventors: Diederik Sybolt WIERSMA, SESTO FIORENTINO (VI) (IT); Camilla PARMEGGIANI, SESTO FIORENTINO (FI) (IT); Jean-Christophe GOMEZ-LAVOCAT, SESTO FIORENTINO (FI) (IT); Kevin VYNCK, SESTO FIORENTINO (FI) (IT)

(73) Assignees: Istituto Italiano Di Tecnologia, GENOVA (IT); CNR - Consiglio Nazionale Delle Ricerche, ROMA (IT)

(21) Appl. No.: 14/647,529

(22) PCT Filed: Nov. 27, 2012
(86) PCT No.: PCT/EP2012/073749

§ 371 Date: May 27, 2015

(51) Int. Cl. B81B 3/00; G02B 26/00; F03G 6/00; G02F 1/1333

(52) U.S. Cl. CPC B81B 3/0029; G02F 1/133362; G02B 26/004; F03G 6/00; Y10S 901/01

(57) ABSTRACT

A liquid crystal elastomer actuator to move in a fluid is described herein. The actuator includes a body with dimensions between 100 nm and 800 μm having a low Reynolds number. The body includes a first and a second spatially separated volume, each comprising a liquid crystal elastomer. The first volume is doped with a first photoactive doping substance to absorb electromagnetic radiation at a first wavelength and the second volume is doped with a second photoactive doping substance to absorb electromagnetic radiation at a second wavelength. The first and second volumes change shape as a consequence of light absorption at the first or second wavelength, defining a first and a second joint. A first absorbance of the first volume at a given wavelength is different than a second absorbance of the second volume at a given wavelength, the first and second absorbance are measured in the same time interval.

### FIELD OF INVENTION

The present invention relates to a liquid crystal elastomer actuator which is capable of displacement in a fluid at a low Reynolds numbers regime driven by light.

### BACKGROUND

In the past decade, due to the increased possibilities offered by micro and nano technologies, there has been a lot of interest in the realization of tiny robotic structures of ever decreasing size; of the scale of insects down to that of micro-organisms, which are able to “move”.

A review of what is available in the field of medicine is given for example in “Current status of Nanomedicine and Medical Nanorobotics” written by Robert A. Freitas Jr. in the Journal of Computational and Theoretical Nanoscience Vol. 2, 1-25, 2005.

Among all possible realization of nano robots, responsive polymeric materials are of interest for a wide range of applications for their potential to be manufactured at low cost, in large quantities and with a large number of properties available. Liquid crystal networks offer a platform for these responsive systems. A variety of dopant molecules has been chosen to make the polymer sensitive to heat, light, pH, humidity and so on. The liquid crystalline units of the network amplify the dopant action, leading to the desired response.

In “A New Opto-Mechanical Effect in Solids” written by H. Finkelmann et al. in Physical Review Letters, Vol. 87, n. 1 (2001), large, reversible shape changes in solids, of between 10% and 400%, has been proposed, which is induced optically by photoisomerizing monodomain nematic elastomers. Empirical and molecular analysis of shape change and its relation to thermal effects is given along with a simple model of the dynamics of response.

From this paper, a new branch of research of liquid crystal elastomers driven by light has started.

The use of elastomers on a macroscopic length scale has been well studied and can be considered now well-known. Thanks to the strength of these materials and large forces when triggered, elastomers are promising for applications such as artificial muscles and actuators, as disclosed for example in Y. Bar-Cohen, Electroactive polymer (EAP) actuators as artificial muscles (SPIE press, 2nd ed., 2004).

However, when it comes to the micrometer-scale, the motion of micrometer-scale objects, in particular in liquids, is very different from that in the macroscopic world, which makes micrometer scale robotics highly interesting from a theoretical point of view. At such length scales inertial forces become small and friction usually dominates. This has important consequences for the way in which objects can move. A good example is that of swimming on a micrometer scale. The Reynolds number, which indicates the ratio between the importance of the inertial and viscous forces, is low on these length scales, meaning that the viscous forces dominate. This situation has been extensively studied by Purcell (E. M. Purcell, Life at low Reynolds numbers, Am. J. Phys. 45, 3 (1977)), who showed that in such environments, the motion of an incompressible Newtonian fluid is described by Stokes equations, which are linear and time-independent.

Thus, a sequence of movements that can be time-reversed cannot possibly lead to a net motion on micrometer length scales. This understanding has generated a large amount of theoretical studies on possible swimming strategies at the micrometer-scale, for example E. Lauga and T. R. Powers, The hydrodynamics of swimming microorganisms, Rep. Prog. Phys. 72, 096601 (2009); Special Ed. on swimming at low Reynolds numbers, J. Phys.: Cond. Matter 21 (May 2009).

In the design of such structures inspiration is often found in biology, where the rules of fluid dynamics at micrometer scale have forced nature to find various strategies for swimming. The most well-known is that of the rotating helical flagella utilized by, e.g., the bacterium E. Coli or that of the asymmetric power and recovery strokes of the algae Chlamydomonas Reinhardtii, see H. C. Berg and R. A. Anderson, Bacteria swim by rotating their flagellar filament, Nature 245, 380 (1973); K. W. Foster and R. D. Smyth, Microbiol. Rev. 44, 572 (1980).

To create artificial structures that can perform micro robotic tasks in liquids has proven not to be easy. Initial promising results were obtained, so far, only for microscopic swimmers (R. Dreyfus et al., Microscopic artificial swimmers, Nature 437, 862 (2005); S. Sanchez, A. A. Solovev, S. M. Harazim, and O. G. Schmidt, Microbots Swimming in the Flowing Streams of Microfluidic Channels, J. Am. Chem. Soc. 133, 701 (2011)) and propellers (L. Zhang, J. J. Abbott, L. Dong, B. E. Kratochvil, D. Bell and B. J. Nelson, Artificial bacterial flagella: Fabrication and magnetic control, Appl. Phys. Lett. 94, 064107 (2009); A. Ghosh and P. Fischer, Controlled propulsion of artificial magnetic nanostructured propellers, Nano Lett. 9, 2243 (2009)) driven by a magnetic field.

In pioneering work, sub-millimeter moving elements were created, driven by either electro staticforces (B. R. Donald, C. G. Levey, C. D. McGray, I. Paprotny, and D. Rus, An untethered, electrostatic, globally controllable MEMS micro-robot, J. of Microelectromechanical Systems 15, 1 (2006)) or magnetic forces (C. Pawashe, S. Floyd, and M. Sitti, Modeling and Experimental Characterization of an Untethered Magnetic Micro-Robot, Int. J. of Robotic Research 28, 1077 (2009)).

### SUMMARY OF THE INVENTION

The aim of the present invention is the development of a liquid crystal elastomer device or actuator which is capable of displacement within a fluid. In particular, the displacement is induced by electromagnetic radiation, in other words light. The dimensions of the device are comprised between 100 nm and 800 μm so that the motion of the device can be considered as a motion of an object having a low Reynolds number. Preferably, the device has a Reynolds number less than or equal to 1, even more preferably lower than 0.1.

The liquid crystal elastomer device or actuator is capable to perform movements, in particular net and measurable displacements, preferably along a chosen direction which is selectable inside a fluid. Described herein, the liquid crystal elastomer device will also be called “the swimmer” for the aforementioned characteristic.

Describe herein, the term “spectrum” has to be understood as referring to one or more frequencies of radiation produced by a radiation source. With “visible spectrum”, a radiation having a wavelength included between approximately 380 nm and approximately 760 nm is generally meant.

The word “color” of radiation here is used interchangeably with the term “spectrum”. However the term color is primarily used to refer to a property of radiation which is visible to an observer.

Additionally, “electromagnetic radiation” and “light” will be used interchangeably, although more specifically light is electromagnetic radiation in the visible spectrum. The present invention is preferably directed to the use of electromagnetic radiation in the visible range, and for this reason the term “light” is preferably used. However, it should be understood that this is not limiting and “light” may also include electromagnetic radiation, either within or outside the visible spectrum or only electromagnetic radiation outside the visible spectrum or only electromagnetic radiation within the visible spectrum.

The general hydrodynamic laws of flow at low Reynolds number are described herein. From the Cauchy equation of continuous media, i.e. Newton's Law, the so called Navier-Stokes equation for an incompressible Newtonian fluid may be derived,

$$ρ ( \frac{\partial v}{\partial t} + ( v \cdot ∇ ) v ) = ρ {f}^{ext} - ∇ p + η {∇}^{2} v , \\ ∇ \cdot v = 0. \qquad ( 1 )$$

Where v is the fluid flow (velocity) field, ρ is the density of the fluid, p is the hydrostatic pressure and η the coefficient of dynamic viscosity. A Newtonian fluid is a fluid for which the relationship between the stress tensor and the shear stress tensor (vᵢⱼ) is linear:

pᵢₖ=−pδᵢₖ+2ηvᵢₖ (2)

It is necessary to add to equation (1) sufficient boundary conditions, usually that the velocity field on the boundary of a submerged body is zero, v|_{∂B}=0. The condition for incompressibility, ∇·v=0, follows from the equation of continuity, and causes the relation between the shear stress tensor and stress tensor to drop a term proportional to δᵢₖvₗₗ. Once we have solved the problem for v and p, the stress tensor is given by equation (2), and the force F and torque M acting upon the organism submerged in fluid are found by integrating along its surface:

F= [symbol] P·ndS, M= [symbol] r×(P·n)dS. (3)

Note that P is the matrix representation of the tensor pᵢₖ. If the Navier-Stokes equation is put in a non-dimensional form, it may be discovered that the solution is parameterized by three constants. The solutions of the Navier-Stokes equation are identical for the same three constants. One of them is the Reynolds number,

$$Re = \frac{VL ρ}{η} ,$$

where V is a typical velocity of the flow, L is the characteristic size of the body and η is the dynamic viscosity. The Reynolds number has many interpretations; One of which is described herein. Considering a body of characteristic size L placed in a steady flow with velocity V, the Reynolds number is the ratio between the importance of inertial effects in the flow, to viscous effect in the flow. “Inertia” is the property of an object to remain at a constant velocity, unless an outside force acts on it. An object with small inertia immediately starts or stops when acted upon by some external or internally generated force. “Viscosity” is the resistance of a fluid to flow under the influence of an applied external force. A low-Reynolds-number flow is one for which viscous forces dominate in the fluid.

Assuming than that the body in issue has a low Reynolds number, it can be assumed that Re=0, thus, assuming also stationarity, equation (1) becomes

η∇²v=∇p−f^{ext}, ∇·v=0, (4)

This equation has a few special features, the two most important ones being: it is linear and independent of time.

If a body—such as the swimmer of the invention—which is small enough to be considered as having a low Reynolds number wants to move inside a fluid, for example by means of deformations, some issues have to be taken into account. First of all, using a way of moving that goes to zero asymptotically or which stops in the middle does not work: there is no inertia at low Reynolds number. Therefore in order to “swim” the body has to keep on moving. In addition to “keep on moving”, at a low Reynolds number what is called the “scallop theorem” applies:

“If the sequence of shapes displayed by the swimming-body deforming in a time-periodic way is identical when viewed after a time-reversal transformation, then the swimmer cannot move on average.”

In other words, a “big” body such as a scallop, having a “hinge” in the shell, lives in a world of high Reynolds numbers and can move by slowly opening and closing fast its shell, hence squirting water and imparting momentum on the fluid. If the scallop was small enough to live in the world of small Reynolds numbers, it would not be able to move with this method. The problem is that it exactly repeats this move in every cycle causing it to oscillate only. More specifically, it moves reciprocally: the motion of a swimmer is called reciprocal if the sequence of shapes which the swimmer assumes is invariant under time-reversal.

Therefore in order to realize a “swimmer” having a body of a small size, i.e. a size small enough to be considered as a body at a low Reynolds number, and capable of moving within a fluid, the swimmer has to perform a non-reciprocal motion. More in detail, the swimmer of the invention includes a body having a size included between 100 nm and 800 μm and moves performing a non-reciprocal motion. The size of the body being comprised between 100 nm and 800 μm means that the biggest dimension of the body is comprised within this range.

In this way, the swimmer of the invention has the ability to perform a “net displacement” inside a fluid, i.e. when it swims, the swimmer can make at least a path wherein a distance between the starting point and the end point of the path made by the swimmer's center of gravity is different from zero, by deforming its body, in the absence of external non-hydrodynamic forces and/or torques.

Inducing controlled motion at the micrometer scale is challenging due to several reasons including energy transfer to the device. Applicants have therefore decided to use light activated liquid crystal elastomers, a choice that solves the problem of energy transfer to the device: sending electromagnetic radiation (i.e. light) to the swimmer's body would allow energy to be transferred from the electromagnetic wave to the molecules. The resulting changes in the material will lead movable parts of the device to perform a sequence of actions that will induce the movement. Therefore, liquid crystal elastomers are used, doped with suitable photoactive substances, in order to convert light into a mechanical force and then used light to control the motion of the various parts of the swimmer.

Preferably, the swimmer's body includes uniaxial liquid crystal(s), i.e. the liquid crystal elastomer used undergoes uniaxial deformations.

The optical control that it is envisioned (i.e. light irradiation of liquid crystal elastomer suitably doped) is very different from that of optical tweezers, in which the electric field gradient in an optical focus is used to create a force. In this latter case, this force is weak and usually of the order of pico newtons. The present invention is based on structural deformations that can be optically induced in polymers, and hence result in much stronger forces (of the order of micro to milli newtons on similar length scales). These structural deformations will be used to create microscopic arms, legs (the above mentioned volumes), and all other elements needed to realize micro robots.

The body of the swimmer of the invention includes at least a volume which comprises liquid crystal elastomer doped with a photoactive substance apt to deform when it is irradiated with electromagnetic radiation at a given wavelength at which the photoactive substance (in the following also called “dye”) absorbs photons. For example, for a body element of a size of 10 μm the dopant concentration is preferably of about 1% molecular concentration, for a body element of 50 μm the dopant concentration is preferably of about 0.1% molecular concentration. According to a preferred embodiment, in uniaxial liquid crystal elastomers, there is an optimum absorption length, in order for the light to be spatially distributed in the best proportions. For example, in case of a rectangular beam of electromagnetic radiation irradiating a volume of the swimmer, this optimum value is approximately a fraction<1 of the beam width, such as ⅕ of the beam's width. So, if in a swimmer with 10 μm-width arms (which are the volumes), the absorption length that should lead to the best deformation is 2 μm. For a swimmer with an arm 50 μm-width, the best absorption length is 10 μm. This applies regardless of the geometry of the volumes, i.e. rectangular “arms” or cylindrical ones. So in general it is possible to alternatively speak about “a swimmer with 10 μm diameter arms”.

The dopant concentration within the volume (arm) follows, but it depends on the molecule which is used to dope the liquid crystal elastomer. In a preferred embodiment, a 1% molar concentration leads to a 5 μm absorption length.

So, for an arm of 10 μm diameter, and one of 50 μm diameter, the following optimum numbers are obtained: 10 μm diameter arms=>2 μm absorption length=>2.5% molar concentration of dopant; 50 μm diameter arms=>10 μm absorption length=>0.5% molar concentration of dopant. This example however simply gives an order of magnitude and depends as said on the size of the volume, on the dye and on the wavelength.

However, it is not sufficient to realize a swimmer having a portion, i.e. the above defined volume, realized in a liquid crystal elastomer properly activated by a suitable photoactive substance to obtain a movable swimmer along a given direction. If a single volume of the swimmer is photoactive and contracts/expands due to light illumination, the resulting net movement is equal to zero, as per the above mentioned scallop theorem, being the swimmer at low Reynolds number.

Therefore the swimmer, in order to obtain a net displacement, at least two degrees of freedom should be present, in other words the swimmer of the invention includes at least two volumes including liquid crystal elastomers, doped with suitable photoactive substances. In this way the swimmer includes at least two movable “arms” (or legs) which can contract and/or expand (in general change shape) when light irradiates them. The volumes which are doped form “joints” of the swimmer, articulations that allow the whole swimmer's body to move. In the following, the two volumes or the two joints which are realized in the swimmer's body are called first and second volume (joint). In order to form two different joints, the two volumes has to be spatially separated one from the other, i.e. they might be part of the same body but the two volumes should move independently one from the other, although a change in shape of one might also deform the other. The important aspect is that the swimmer's body includes two joints and thus two degrees of freedom.

Due to the size of the swimmer, which is—as said—comprised between 100 nm and 800 μm, it is extremely complex to illuminate selectively only a portion of the swimmer body. In other words, the swimmer is preferably irradiated by electromagnetic radiation in its entirety, due to the fact that irradiating only some portion of the same can be cumbersome. Due to this problem, a swimmer body comprising two volumes including liquid crystal elastomers, doped with suitable photoactive substances so as to absorb light, is not capable to swim in a non-reciprocal motion. For example, the swimmer when irradiated uniformly will not produce a net displacement due to the fact that the movement of the two volumes, i.e. their contraction or extension, is symmetrical in shape in case the two volumes have the same reaction (e.g. they deform in the same way) to light absorption. These two volumes therefore create a movement which is symmetric in shape and at low Reynolds number this prevents a displacement, it only allows an oscillatory motion back and forth.

The movement performed by the swimmer has to be asymmetric also in shape during time, which means in other words that the changes in shape due to light absorptions performed by the two different volumes have to be different, so as to create an asymmetric movement. According to the invention an asymmetric light absorption should be realized in the swimmer. For example, the change in shape due to light absorption in the first volume and in the second volume should be different or the change in shape of the first volume and the second volume should be performed in different time steps again in order to perform an asymmetric movement, which can be considered anyhow a difference in light absorption between the two volumes (one absorbance being equal substantially to zero).

The characteristics of light absorption of the first volume can be different to the characteristics of light absorption of the second volume in a given time interval, giving rise to different change in shape of the first and second volume for many different reasons. According to a preferred embodiment, the light absorption of the first volume takes place at a different wavelength than the light absorption in the second volume. This is due for example by a difference in the photoactive substance (or dye) used to dope the first and the second volume. Just by way of example, the first volume might absorb light—and thus change shape—when irradiated by red light. The second volume does not absorb red light at all therefore does not contract or expand when red light is impinging the swimmer's body. Conversely, the second volume absorbs blue light, which is not absorbed by the first volume. In this way, by shining alternatively the swimmer using red and blue light, and realizing a change in shape in the first and the second volume in the body so that the final motion is asymmetrical in shape, the swimmer can move. It can be seen thus that in different time intervals, taken for example identical in duration to the time interval in which red (blue) light is shining on the swimmer, that the absorption of the two volumes is very different: During T1 red light is shining in the two volumes, the light absorption of the first volume is high, the light absorption of the second negligible; During T2 blue light is shining in the two volumes, the light absorption of the second volume is high, the light absorption of the first volume negligible.

However, a difference in the wavelengths of the light which is absorbed is not the only possible difference in absorption which leads to a shape change difference or to an “intermittent” shape change, e.g. the shape change depends on light modulation, in other words on the wavelength of the incident light at a given time, that can be present among the two volumes. Another difference can be, according to another embodiment of the present invention, in the amount of photons which are absorbed per unit of time and per unit of volume by one of the two volumes with respect to the other of the two volumes. As an example, in a preferred embodiment, both volumes are doped with a photoactive substance (dye) absorbing light at the same wavelength. A different amount of absorbed photons per unit of time and per unit of volume changes the contraction/expansion characteristics (i.e. the shape change) of the volume itself, i.e. a higher doping leads to a greater/wider movement. Therefore, the first and the second volume can be differently doped, i.e. the suitable photoactive substance is present in different concentrations in the first and second volume, for example in a two steps fabrication process as better detailed in the following, or “reducing” the dye concentration in one of the volumes “burning” the volume locally. In the following with the term “burning” the action of a laser beam or of other suitable radiation source which can emit an electromagnetic radiation which destroy the dye, in particular it destroys its photoactivity. Additionally, the dye can be bleached. Therefore, the realization of a “burning spot” into one of the volumes locally reduces the dye concentration in that volume because in the burning spot the dye is effectively not present (i.e. its photo-absorption is stopped).

Alternatively, according to a different embodiment of the present invention, the amount of photons which are absorbed by one of the volumes per unit of time and per unit of volume can differ among the first and second volume due to the presence of a photonic resonant structure.

Photonic structures are wavelength scale structures with periodicity on the order of the wavelength of light. Therefore, these structures manipulate the propagation of light. For example, photonic structures may confine the light in a certain portion of the swimmer's body and/or may avoid that light enters and/or propagate into another portions.

Positioning in one of the volumes, or externally with respect to the volumes, a photonic structure which is resonant at the wavelength of the radiation which impinges the body enhances the electromagnetic field at the volume where the photonic structure is present (or effective) so as to increase the light absorption of that specific volume when compared to the absorption which takes place in the other volume without photonic resonant structure.

It is not necessary that the photonic structure is present exactly within one of the two volumes in order to enhance or suppress light absorption: the photonic structure can be located in any portion of the swimmer body as long as the action of the electromagnetic field is the desired one, i.e. the action of the photonic structure on the electromagnetic field created by the electromagnetic radiation (light) impinging on the swimmer is altered by the photonic structure presence so that the field is either enhanced or suppressed in one of the two volumes so as to differentiate the absorption of light in the first with respect to the second volume. In addition, the photonic structure can also be placed outside the body, such as for example on top of the body of the swimmer.

According to an additional preferred embodiment of the invention, the difference in absorption may also depend on the shape of the swimmer. In other words, the first or the second volume might absorb light differently depending on the geometrical shape in the 3-dimensional space of the body of the swimmer.

Indeed, in this preferred embodiment, both first and second volume might be including the same liquid crystal elastomer(s), doped with the same photoactive substance(s) which absorbs light at the same wavelength. However the swimmer further includes a photonic structure which is able of trapping and/or controlling the spatial distribution of the light within the swimmer's body.

For example in the case the swimmer body has two separated volumes forming two joints which “move” due to the absorption of light at the same wavelength, in case of light irradiation at the correct wavelength, both volumes without the presence of the photonic structure would absorb light and bend. However, the photonic structure can be so designed that, in the “relaxed” configuration, i.e. when both volumes are not contracted, the light which will impinge the body is confined outside the second volume. This can happen for example in case this incident wavelength coincides to a photonic band gap of the photonic structure. When a contraction of the first volume takes place, a change in the swimmer's body shape is also taking place and thus modifying the geometrical characteristics of the photonic structure. This may result in a change of the light's confinement exerted by the photonic structure: a deformation of the photonic structure changes its band gaps and the resonances in such a way that now light at the same wavelength that before was confined outside the volume now can also be absorbed by the second volume producing a contraction of the same.

This further causes a new change in shape of the photonic structure modifying again its effects of the light. In this case the difference in absorbance is present when the absorbance is measured within the same time interval, i.e. the absorbance of the two volumes are for example substantially zero and a fixed value when it comes to the first and second volume when measured during time interval T1, and they are substantially identical when measured during a subsequent time interval T2, after the photonic structure modification.

A possible example is a swimmer including a periodically-nanostructured, two-dimensional, photonic crystal. In certain frequency (wavelength) ranges, the propagation of light inside the volume where the photonic crystal is present can be forbidden in the material due to the existence of a photonic band gap. Thus, light will be confined in the spatial regions where it can propagate, and the material deformation will occur only in these regions, for example if the photonic crystal is in the second volume, only the first volume deforms. The deformation will induce a modification of the lattice constant for example a reduction of the lattice period. As a result, the photonic crystal could allow for light to propagate and also the second volume could contract.

The swimmer of the invention therefore is suitably designed in order to have two volumes which absorb light differently, and the difference is for example based, according to some preferred embodiments, either to a difference in the wavelength absorbed, in the amount of photon absorbed, or on the fact that the absorbance depends on the shape of the swimmer's body in a different way. In the latter case, more specifically, the swimmer includes a photonic resonant structure which allows, inhibits or modifies the absorbance of light at a given wavelength by the first or second volume.

Alternatively, in order to change the characteristic of the photonic structure, again a different radiation at a different wavelength can be used: the light in a first case for example can be trapped only in the first volume, but changing the wavelength of the light, it becomes trapped only in the second volume due to the different action on the light of the photonic structure.

Examples of photonic structures that can be used in the swimmer of the present invention are for example photonic crystals, resonators, gratings or nano-antennae. The provision of a photonic structure shape-dependent in the swimmer also allows a movement of the swimmer itself without light modulation. Indeed, as seen in the first example, in case there is a light absorption difference due to the different light wavelength that it absorbed, there should be a modulation of the different wavelengths used (i.e. first red light should be irradiated onto the swimmer, then blue, then both etc.). In case of a photonic structure which affects the light absorption depending on the geometrical form or shape of the swimmer, the need of light modulation is not present anymore.

As a preferred embodiment, a swimmer having a first and second volume and a photonic structure which, when no light is irradiated, is apt to confine the light outside the second volume is considered. When light is irradiated, it is absorbed only by the first volume, and this causes a contraction or deformation of the same. This first shape change due to the contraction of the material forming the first volume changes in turn the geometrical shape of the photonic structure. In a photonic structure, a modification of the geometrical shape modifies the effects that the photonic structure has on confinement of light: in the preferred embodiment the photonic structure now allows light to be absorbed by the second volume too. The new absorption cause a contraction or deformation of the second volume, which causes a further shape change. In this new geometrical configuration, the photonic structure may now hinder the absorption of light from the first volume, and so on.

From the above it is clear that in the described preferred embodiment, the photonic structure has to be located in the vicinity of the swimmer body in such a way that environmental change when the first and/or the second volumes contract or deform due to light absorption will change its optical behaviour. The term “in the vicinity” means that the effect of the photonic structure changes the electromagnetic radiation distribution inside the swimmer's body. Therefore the “distance between the photonic structure and the swimmer's body is such that this influence on the radiation's distribution within the body can be observed.

Preferably, the photonic structure is embedded within the swimmer's body.

The possibility of avoiding light modulation is definitely advantageous for considering a control of swimmer made in a rather easy manner.

Preferably, the change in shape mentioned above in any of the various aspects of the invention described, according to a preferred embodiment of the invention, is considered as a rotation or bending of the joint by an angle, i.e. the change in shape of the first and/or second volume includes a rotation of the joint by a given amount. The two change in shape differs, i.e. the shape change of the first volume is different than the shape change of the second volume, if the two angles are different. For example, bending of an “arm” of the swimmer may imply a rotation around the joint of above 45°.

Structuring elastomers on a length scale of micrometers, with nanometer scale precision, and combine them with other organic and even inorganic structures, using direct laser writing, will allow to create complex photonic structures that have both a mechanical as well as an optical response, which we will use as basis to form microscopic photonic robots. Thanks to that swimmers of various kinds, on a micrometer length scale, controlled and driven by light are realized. That is, micro robots that can swim in liquids, walk or crawl, and when at destination perform specific tasks. In one embodiment of the present invention, a preferred inorganic structure is a photonic crystal.

Liquid crystals are well-known substances and their understanding is part of the general knowledge of the technical field the present invention pertains to.

According to the present invention, the liquid crystal is a liquid crystal elastomer (also herein indicated as LCE), which provides the mechanical component of the micro robot. Embedded into the LCE is a dye, which provides the control component and the energy of the micro robot. In different embodiments of the present invention, the dye can be incorporated in the polymer chain of the LCE or being attached to the LCE polymer or dispersed in it.

According to a generally accepted classification, LCEs are comprised in the categories of nematic elastomers, cholesteric elastomers and smectic elastomers (Warner and Terentjev, ibid.).

The present invention applies to all three categories, preferably to nematic LCEs.

Liquid crystal elastomers are rubber-like polymers which can exhibit large structural changes. A general description on LCEs is found in M. Warner and E. M. Terentjev Liquid Crystals Elastomers, Clarendon Press 2003. LCEs are formed by crosslinked networks of mesogenic polymer chains bearing mesogenic groups either incorporated into the polymer chain or as a side groups and capable of spontaneous ordering. Side-chain liquid crystals usable in the present invention are disclosed in GB 2146787. Crosslinking must be carried out in order to allow the polymer to retain elastomeric properties.

Liquid crystal elastomers disclosed in U57122229 are suitable for use in the present invention.

Mesogenic aromatic molecules are well known in the art of LCEs and can be generally applied to the present invention.

Generally, mesogenic molecules are formed by one or more aromatic or heteroaromatic rings, connected together by linkers that allow a restriction of the movement (for example O—C═O) necessary to obtain liquid-crystalline properties.

### BRIEF DESCRIPTION OF THE DRAWINGS

The present invention will be better understood by non-limiting reference to the appended drawings in which:

FIGS. 1a-1e are schematic drawings of a first swimmer realized according to a first embodiment of the present invention and moving according to the method of the invention;

FIGS. 2a-2d are schematic drawings of a second swimmer realized according to a second embodiment of the present invention and moving according to the method of the invention;

FIGS. 3a-3e are schematic drawings of a third swimmer realized according to a third embodiment of the present invention and moving according to the method of the invention;

FIGS. 4a-4e are schematic drawings of a third swimmer realized according to a fourth embodiment of the present invention and moving according to the method of the invention;

FIGS. 5a-5c are schematic drawings of a detail of a swimmer according to an embodiment of embodiment of the present invention in different configurations; and

FIGS. 6a-6d are schematic drawing of a further embodiment of a swimmer.

### DESCRIPTION OF THE PREFERRED EMBODIMENTS

In one embodiment of the present invention, the LCE can be an organopolysiloxane having mesogenic moiety as a pendant side chain, as disclosed in U.S. Pat. No. 7,122,229. The organopolysiloxane has the following formula (I)

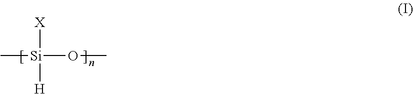

wherein X is a C₁-C₂₀ linear or branched alkyl group, n is between about 20 and about 500. Methyl is a preferred alkyl Organopolysiloxane LCE suitable for the present invention are also disclosed in U.S. Pat. No. 4,388,453 and U.S. Pat. No. 5,385,690.

Mesogenic groups can be attached to the organopolysiloxane group or incorporated into the organopolysiloxane chain.

Any mesogenic molecule can be used in the present invention, provided it allows chemical coupling or incorporation with a dye. The mesogenic molecule may itself be a dye.

Mesogenic groups usable in the present invention are disclosed for example in U.S. Pat. No. 5,164,111.

Preferred mesogenic groups have a biphenyl structure, as disclosed for example in U.S. Pat. No. 4,293,435.

In one embodiment of the present invention, the mesogenic group of the biphenyl type is a compound of general formula (II)

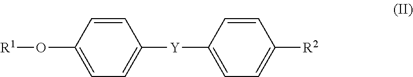

wherein Y is selected from the group consisting of a Schiff base, a diazo compound, an azoxy compound, a nitrone, a stilbene, an ester or is not present; R¹ and R², which can be the same or different, are selected from the group consisting of C₁-C₂₀ linear or branched alkyl, optionally containing 1-3 halogen atoms, R² can also be a C₁-C₂₀ linear or branched alkoxy, cyano, amino, nitro or halogen.

In one embodiment of the present invention, the mesogenic group of the biphenyl type is a compound of general formula (III)

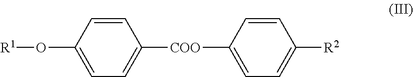

wherein R¹ is a C₂-C₂₀ linear or branched alkenyl, containing at least one C—C double bond, R² is selected from the group consisting of C₁-C₂₀ linear or branched alkyl or alkoxy, amino and cyano.

Mesogenic groups containing cyanoacrylic acid ester portions suitable for the purpose of the present invention are disclosed in U.S. Pat. No. 5,151,481, GB 2146787 and Makromol. Chem. (1985), 186, 2639-47, Polymer Communications (1988), 24, 364-365, Makromol. Che. Rapid Commun. (1984), 5, 393-398.

In an embodiment of the present invention, polyacrylate liquid crystals have the following general formula (IV)

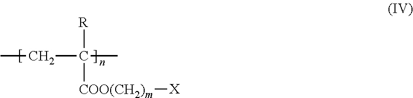

wherein n shows the repeating monomeric unit in the polymer chain and is determined by the degree of polymerization (CH₂)ₘ—X is the side-chain mesogenic portion, m is at least 1 up to 20, and R is selected from the group consisting of hydrogen, C₁-C₂₀, linear or branched alkyl and halogen.

In another embodiment of the present invention, the polyacrylate liquid crystal can be prepared according to a method disclosed in GB 92037030.8. the polyacrylate copolymer has the following repeat unit:

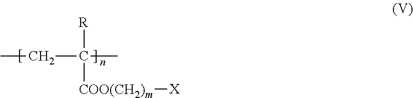

wherein R₁ and R₂ is are independently C₁-C₂₀ linear or branched alkyl or hydrogen, R₃ is selected from the group consisting of C₁-C₂₀ linear or branched alkyl, hydrogen or chlorine, m is 0 or an integer between 1 and 20, W is a linkage group COO or OOC, O and X is a mesogenic group.

The polymer backbone and the mesogenic group can be spaced apart by a bridge imparting further flexibility to the molecule. Example of bridge is a methylene chain, optionally branched. The minimum length of the methylene chain is of course the single methylene group. There is no virtual limit of the chain length, provided that the polymer and the mesogenic portion do not loose their property as liquid crystal.

Other liquid crystals elastomers suitable for the present invention are disclosed in U.S. Pat. No. 5,385,690.

Other acrylic monomers suitable for the present invention are disclosed in WO2001040850.

Another embodiment of the present invention provides LCEs where the polymer backbone is made by the mesogenic molecule, provided it can be polymerized. For example, mesogenic groups bearing acrylate or methacrylate moieties.

An interesting reactive LC monomer useful in the present invention is

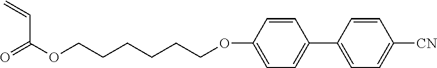 [SMILES: C=CC(=O)OCCCCCCOc1ccc(-c2ccc(C#N)cc2)cc1]

disclosed together its use in building up LCE in Sawa et al. Macromolecules 2010, 43, 4362-4369.

Other preferred embodiments of the present invention are based on the following compounds and related actuators disclosed in Min-Hui Li, Advanced Materials, 2003, 15, No. 7-8, April 17, 569-572:

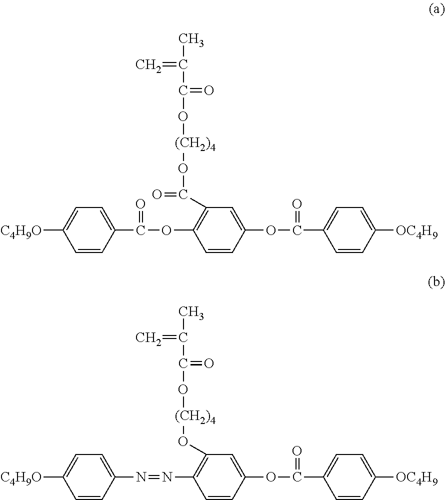

Crosslinking liquid crystal polymers is due to achieve elastomeric properties. Any suitable crosslinker can be used to the purpose of the present invention. The choice is made by the person of ordinary skill in this art, depending on the well-known chemistry of the polymerizable group. The crosslinker can optionally be a mesogenic molecule.

By way of example, crosslinkers disclosed in U.S. Pat. No. 7,122,29 can be used in the present invention.

Other examples of crosslinking agents are pentaerythritol tetraacrylate, 1,6 hexanediol diacrylate, the following compound

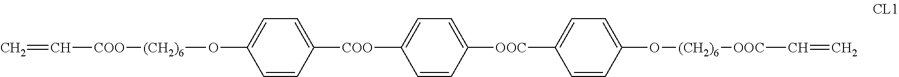

Crosslinking degree is determined by the skilled on the art depending on the wished degree of elasticity. By way of example, from about 5% to about 25% crosslink density is satisfactory.

1,6-Hexanediol diacrylate and the above CL2 are the most preferred.

Other preferred crosslinkers are

1,6-hexanedioldiacrylate or

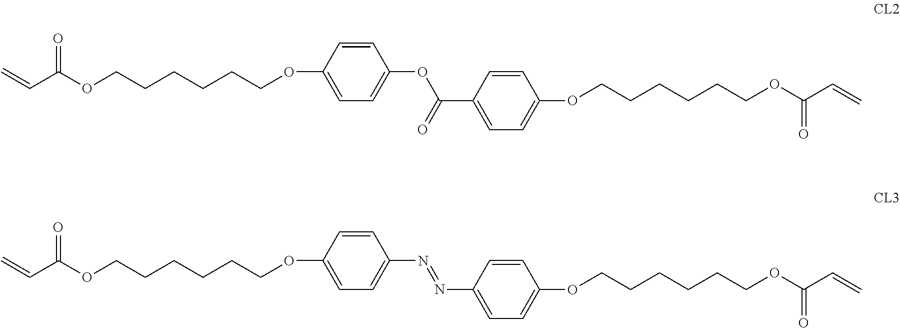

Another essential element of the present invention is the dye.

Any dye responding to the requirements of the present invention, namely the LCE is capable to perform a displacement in a liquid when irradiated, can be used.

Example of dyes usable in the present invention are azo dyes, which are well-known in the art. Examples of azo dyes are provided in the common general knowledge, but see also U.S. Pat. No. 7,122,229.

In an embodiment of the present invention, the dye used is methyl 8-(4′-pentylbiphenyl-4-yl)-2-phenyl-2-(4-fluorophenyl)-2H-naphtho[1,2-b]pyran-5-carboxylate, disclosed together other useful dyes in Kosa et al. Nature, vol. 485, 12 May 2012, 347-349.

In a preferred embodiment of the present invention, mesogenic aromatic molecules can be described by the following general formula (VI):

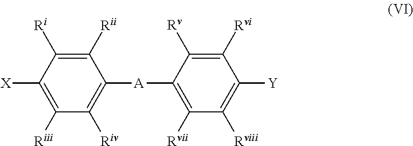

where the groups Rⁱ-R^{viii}, which can be the same or different are independently hydrogen; a halogen atom; nitro; amino cyano; C₁-C₆ linear or branched alkyl chain, said chain optionally containing one or more double bonds, said chain optionally being substituted by one or more phenyl rings; a 5- or 6-members carbocyclic ring, optionally containing one or more heteroatoms selected from the group consisting of N, O and S, said ring optionally being aromatic;

A, which can also be absent, is a double bond-containing linker which can confer stiffness the compound (I), the linker is selected from the group consisting of a C₁-C₁₂ carbon chain, —N═N— and —CH═N—; the latter two being preferred;

X and Y, which can be the same or different, are NO₂ or organic weakly polar groups, preferably —OCH₃ or —CN.

For the purposes of the present invention, the term “weakly polar groups” is fully understood by a person of ordinary skilled in the art, by resorting to the common general knowledge, for example textbooks and manuals.

Particularly preferred liquid crystal molecules are:

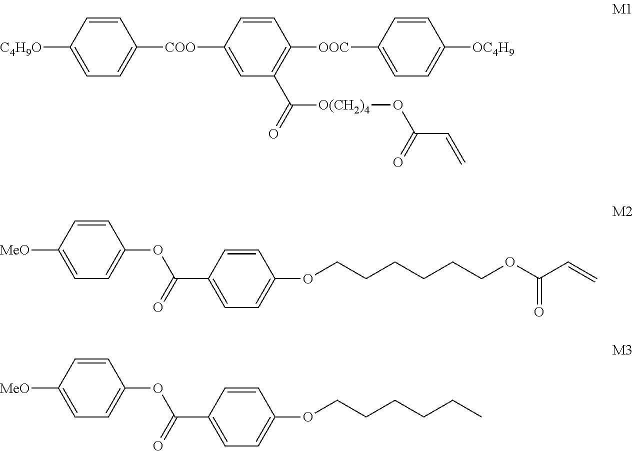

M3 is a liquid crystal capable of being used also as a solvent (LC solvents).

These compounds are prepared according to well-known methods [M1: Donald L. Thomsen III, Patrick Keller, Jawad Naciri, Roger Pink, Hong Jeon, Devanand Shenoy, and Banahalli R. Ratna, Macromolecules, 34 (17), 5868-5875; M2: J. D. Marty, M. Mauzac, C. Fournier, I. Rico-Lattes, A. Lattes, Liq. Cryst. 2002, 29, 529-536; M3 is also commercial available (Ambinter)].

Particularly preferred dyes are:

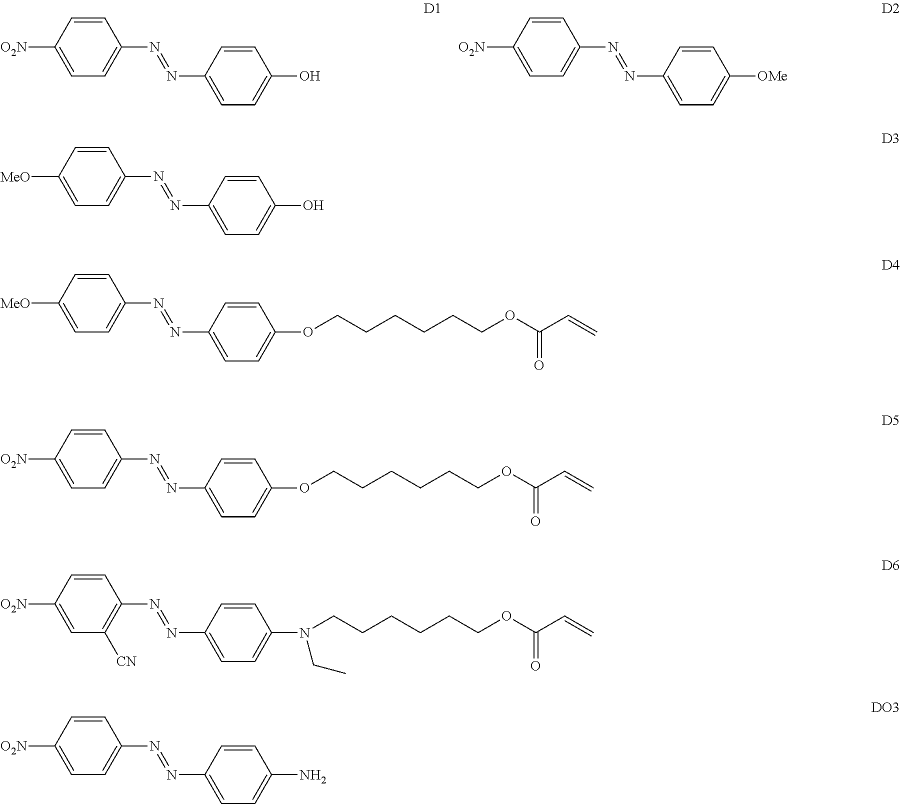

said dyes were dispersed into the liquid crystal.

Any conventional means of dispersion can be used. For example, dispersion of the dye is achieved by slow addition of a solution of the dye in a suitable solvent (usually Toluene) directly to the preformed LCE suspended in a solvent, such as Hexane for example.

In another preferred embodiment, dyes D4-D6 were connected to the liquid crystal by photopolymerization.

The compounds D1 and DO3 are commercially available (Sigma-Aldrich) or can be prepared according to well-known methods (D1: Haghbeen, Kamaldin; Tan, Eng Wui Journal of Organic Chemistry, 1998, vol. 63, #13 p. 4503-4505). The compound D2 is also commercially available (Sigma-Aldrich) or can be prepared according to: Davey, Lee, Miller, Marks J. Org. Chem., Vol. 64, No. 13, 1999 4976; D3 as per Junge, Denise M.; McGrath, Dominic V. Chemical Communications, 1997 #9 p. 857-858; D4 as per Moeller, Andrea; Czajka, Uta; Bergmann, Volker; Lindau, Juergen; Arnold, Manfred; Kuschel, Frank Zeitschrift fuer Chemie, 1987, vol. 27, #6 p. 218-219; and D5 as per Pittelkow, Michael; Kamounah, Fadhil S.; Boas, Ulrik; Pedersen, Brian; Christensen, Joern B. Synthesis, 2004, #15 p. 2485-2492.

Polymerization is carried out according to well-known method, for example as disclosed in WO01/40850 or in U.S. Pat. No. 5,151,481., Donald L. Thomsen III, Patrick Keller, Jawad Naciri, Roger Pink, Hong Jeon, Devanand Shenoy, and Banahalli R. Ratna, Macromolecules, 34 (17), 5868-5875;

In a preferred embodiment, polymerization is photo-induced radical polymerization, where the preferred photoinitiator is one of

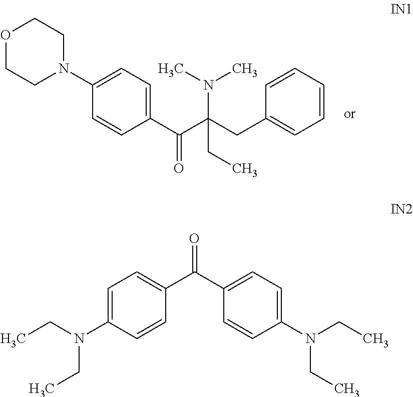 [SMILES: CCC(Cc1ccccc1)(C(=O)c1ccc(N2CCOCC2)cc1)N(C)C ; CCN(CC)c1ccc(C(=O)c2ccc(N(CC)CC)cc2)cc1]

A mixture of a monomer, preferably an acrylic monomer as above disclosed, a dye, a cross-linker and a photoinitiator is prepared.

The percentages of the mixture are determined in view of the final properties needed for the resulting material.

In a preferred embodiment of the present invention, the mixture is formed by (w/w):

### Monomer: 70-90%,

### Cross-linker: 2-25%,

### Dye: 0.01-15%

### Photoinitiator: 0.5-10%.

In an exemplary embodiment, the mixture is formed by

### IN1: 1.50%

### D6: 1.30%

### M1: 18%

### M2: 68.2%

1,6 hexanediol diacrylate: 11%

The actuator obtained according to the present invention from the above mixture represents a preferred embodiment.

Another exemplary embodiment of the present invention is an actuator obtained according to the present invention from the following mixture:

1.30% (w/w) D6, 18% (w/w) M1, 68.2% (w/w) M2, 1.50% (w/w) IN1 and 11% (w/w) 1,6 hexanedioldiacrylate

The actuator according to the present invention can be prepared with well-known writing procedures.

Conventionally, a mixture comprising liquid crystal molecules, one or more dyes, a crosslinker and a polymerization initiator is introduced in suitable equipment at a temperature in which the liquid crystal is in an isotropic state. Subsequently, the liquid crystal is brought to its nematic phase, and converted into a liquid crystal elastomer by polymerization. Shaping of the actuator can be done at the same time. Final development is performed.

According to well-known methods a sacrificial layer, in a preferred embodiment polyimide or poly(vinyl)alcohol (PVA), is coated on two glass slides, see for example U.S. Pat. No. 6,312,770 or Buguin A., et al JACS 2006, 128, 1088-1089. A layer of few microns, typically 2-5, is deposited on each glass slide.

Rubbing, either manual or motorized, is made in the sacrificial layer, so that a preferential direction will be taken by the liquid crystals molecules.

By using the two glass slides placed upside-down, and by reversing the direction of rubbing, a glass cell is obtained. A spacer, in a preferred embodiment an aluminum foil or a set of calibrated glass spheres, is used between the two glass slides. The glass cell has usually a separation gap of about 40 microns, but this depends on the size of the final actuator.

The above mixture is infiltrated in the cell at a temperature where the mixture is in a isotropic state, and this depends on the mixture used.

The final writing is done when the liquid crystal moieties are aligned with the rubbing direction, i.e. the liquid crystal is in the nematic phase. This provides a better response to light. The following temperature cycle is performed:

a) infiltration in the cell at isotropic temperature, for example>80° C.;
b) slow decrease toward the nematic temperature, for example about 50° C. The descent slope is not critical, but preferably is slow, more preferably from 1° C./min to 5° C./min.
c) performing writing step at the temperature within the nematic range typical of each mixture used.

In a preferred embodiment, the writing step is performed with a 2-Photon Direct Laser Writing device. However, other photolithographic systems can be used, for example with direct and reverse resist.

A femto laser is tightly focused onto a sample, so that polymerization occurs by a 2-photon absorption process. This process is non linear by nature and a given amount of power is required before the polymerization occurs. The voxel of polymerization is therefore determined by the polymerization threshold as a function of exposure time and surface intensity, see Two-Photon Absorbing Materials and Two-Photon-Induced Chemistry, Rumi, Mariacristina and Barlow, Stephen and Wang, Jing and Perry, Joseph W. and Marder, Seth R., Advances in Polymer Science, vol 213, 2008]

d) the polymerized and unpolymerized structures are finally separated in a developing bath. The bath is a solvent, preferably with high flash and boiling point and low vapor pressure. These kind of solvents are well-known in the art. Preferred solvents are selected from the group consisting of: N-methyl pyrrolidone (NMP), dimethyl sulfoxide (DMSO), ethyl lactate and propylene glycol monomethyl ether acetate (PGMEA).

If desired, holes or defects with a size of from 300 nm to 1 μm can be created during the writing step c). These holes or defects can be subsequently infiltrated with a photoresist with high refractive index to create a photonic crystal.

If desired, “burning” of a selected zone of the structure with the laser (shining longer and with more intensity) the efficiency of the dye, in particular azobenzene dye, drops to zero.

The development is made in a dark ‘yellow’ room to prevent UV pollution. The laser emits at 780 nm and does not polymerize the mixture. Due to a strong intensity of the focused beam, non linear (2 photon) absorption occurs. The mixture sees photons of wavelength 390 nm in the focus spot. So it's polymerized only when the laser is ON and focused.

With reference to the appended drawings, with 1 a swimmer realized according to the present invention is globally indicated.

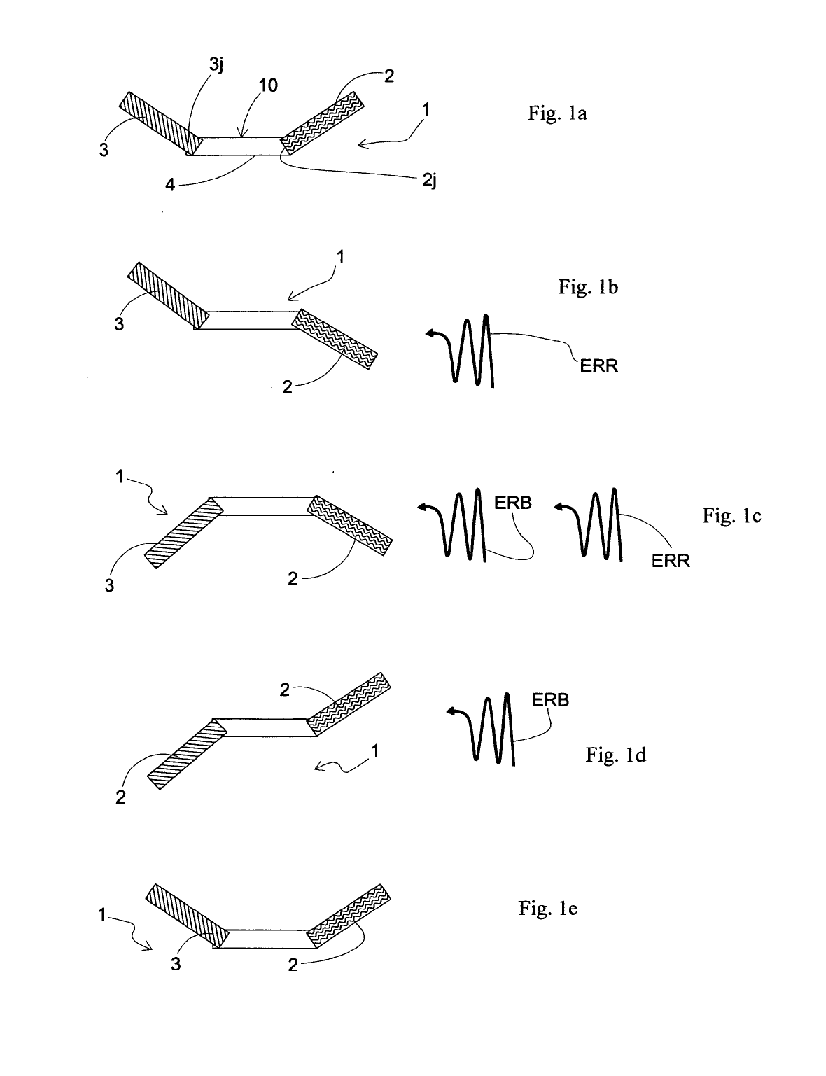

With initial reference to FIGS. 1a-1e, the swimmer 1 includes a body 10 in which volumes 2 and 3 are defined. Volumes 2,3 form joints 2j,3j and can be considered as “arms” of the swimmer 1. The two volumes are connected by a third volume 4, preferably non doped. Volumes 2,3 are realized in a liquid crystal elastomer doped with a photoactive substance: volume 2 is doped with a substance that absorbs red electromagnetic radiation (first wavelength), while volume 3 is doped with a substance that absorbs blue electromagnetic radiation (second wavelength).

In FIG. 1a the “relaxed” configuration of the swimmer is shown, i.e. no light at the first or second wavelength is impinging onto body 10.

In a first step, electromagnetic radiation ERR having a first wavelength (red) is irradiating body 10. Due to the absorption of volume 2 of such a radiation, the first volume changes shape and the “arm” moves (see FIG. 1b), substantially rotating around the joint formed in the body. The rotation is due to the arm's bending. The absorption of light by the second volume is substantially negligible due to the fact that it is doped with a photoactive substance absorbing a different wavelength (blue).

In a second step depicted in FIG. 1c, electromagnetic radiation ERB at a second wavelength (blue) is now irradiating body 10, in addition to the radiation ERR at the first wavelength. This time, volume 3 absorbs such a radiation, while the absorbance of volume 2 is as in the previous step. Volume 3 moves in the depicted position due to contraction or bending, substantially rotating of a given angle around the joint.

In a third step, with reference to FIG. 1d, electromagnetic radiation ERB at the second wavelength (blue) is irradiating again body 10, causing a new movement of volume 2, due to relaxation (i.e. the volume is not contracted anymore because radiation is not impinging the same). Next, electromagnetic radiation ERB at the second wavelength (blue) also switched off from irradiating body 10, causing the movement of the second volume 3 (see FIG. 1e) in a relaxed (unbent) position, and the configuration of actuator (or swimmer) 1 is now analogous to the starting configuration depicted in FIG. 1a.

It can be seen that the movement performed by swimmer 1 is non-reciprocal: the time reversed sequence of configurations 1e->1d->1c->1b->1a is different from the sequence 1a->1b->1c->1d->1e.

In this case the difference in absorption between the first and the second volume is given by a difference in the absorbed wavelength.

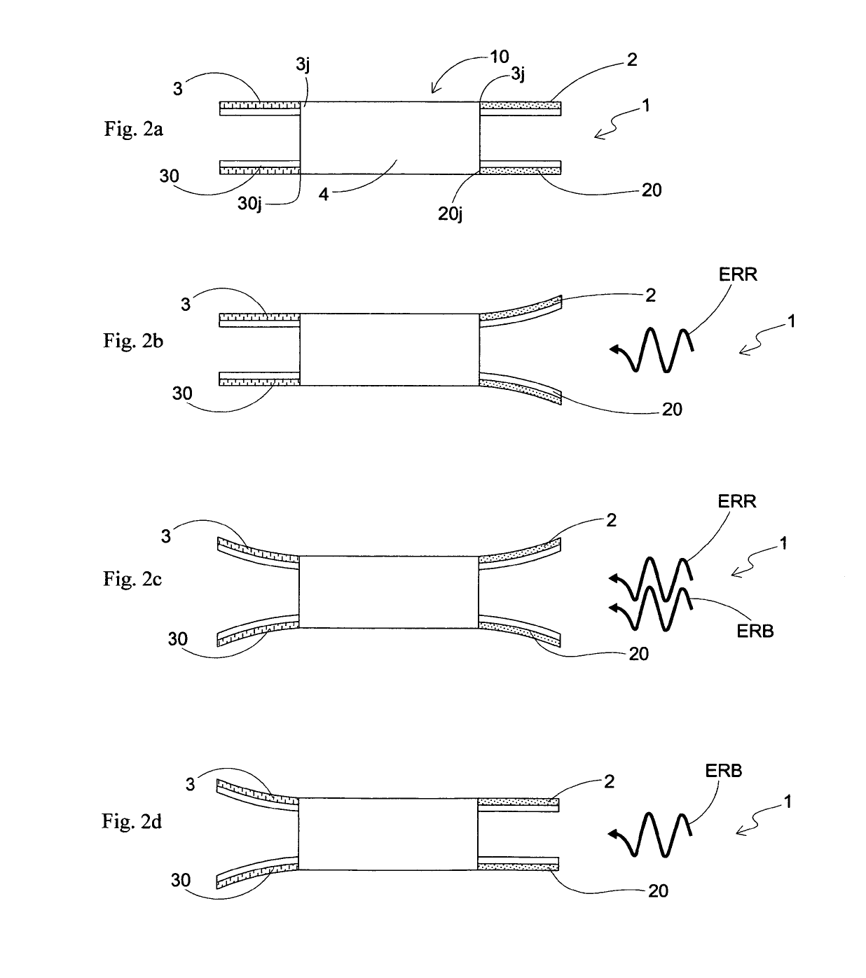

With reference now to FIG. 2a-2d, a different embodiment of the invention is depicted. The swimmer 1 in this case comprises a body 10 which includes four volumes, a first and a third volume 2 and 20 which are realized in a liquid crystal elastomer doped with a photoactive substance volume that absorbs red electromagnetic radiation (first wavelength); and a second and a fourth volume 3 and 30, which are realized in a liquid crystal elastomer doped with a photoactive substance volume that absorbs blue electromagnetic radiation (second wavelength). Consequently, four joints 2j,20j,3j,30j are also realized in the body 10. The various volumes are connected on the two opposite sides of a non-doped volume 4, realizing substantially two “arms” per side of the swimmer (the sides can be considered as the top and bottom or left and right of the swimmer).

The electromagnetic radiation is irradiating the body 10 according to the following table 1 (reference is made to the appended drawings, time in this table is going from left to right):

TABLE 1

| | | Red light | Red and blue | Blue light | No light |
|---|---|---|---|---|---|
| | No light | ERR | light (FIG. 2c) | (FIG. | (FIG. |
| | (FIG. 2a) | (FIG. 2b) | ERR + ERB | 2d) ERB | 2a) |
| Volumes 2 | closed | Open | open | closed | closed |
| and 20 | | | | | |
| Volumes 3 | closed | closed | open | Open | closed |
| and 30 | | | | | |

Indeed, the light will induced a contraction in the length of the volumes which absorb light at the specific wavelength. So, when red light will be shone on the swimmer 1, both volumes 2,20 absorbing red wavelength will contract in the x-direction. This will lead to a bending toward the outside, therefore, the swimmer 1 will open its “arms” 2 and 20. The same applies when blue light is illuminating body 10, thus “arms” 3 and 30 open.

In this case the difference in absorption between the first (third) and the second (fourth) volume 2,3 or 20,30 is given by a difference in the absorbed wavelength.

Preferred dimensions of the swimmer 1 are the following:

Body length: from 5 μm to 500 μm,
Arm/leg length: from 1.5 μm to 150 μm,
Speed of arm/leg when irradiated: from 1 μm/s to 500 μm/s,
Velocity of the swimmer in straight motion: from 10 nm/s to 5 μm/s.

With leads to the following these numbers: Reynolds number: from 10⁻⁴ to 10⁻⁶.

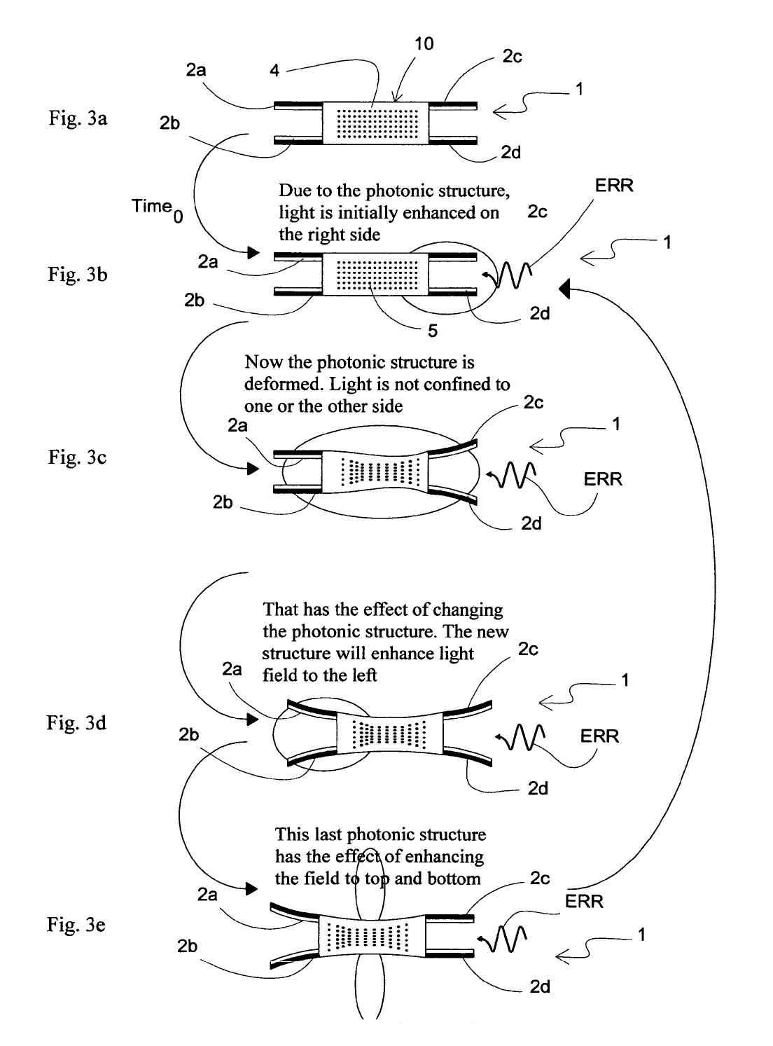

The embodiment of FIG. 3a-3e is now discussed. The swimmer 1 has a geometrical shape which resembles the swimmer of the second embodiment of FIGS. 2a-2d, having a non-doped volume 4 from the two opposite sides of which two opposite couples of volumes, named with the reference numerals first couple 2a, 2b, and second couple 2c, 2d, depart. All four volumes are realized in a liquid crystal elastomer doped with a photoactive substance volume that absorbs a first electromagnetic radiation, such as for example a red radiation. All volumes have substantially the same dopant concentration. Swimmer 1 in addition includes a photonic structure 5.

In FIG. 3a the “relaxed” configuration of the swimmer is shown, i.e. no light at the first wavelength is impinging onto body 10 and thus no change of shape takes place in any of the four volumes.

In the following steps, light at the first wavelength is always impinging the body 10.

In FIG. 3b light at the first wavelength is irradiated to the swimmer 1. Due to the presence of the photonic structure 5, light at the first wavelength cannot propagate in the first couple of volumes 2a,2b: the electromagnetic field is enhanced on the side of the swimmer in which volumes 2c and 2d are present.

A possible embodiment is a swimmer of body length 6 μm, with four arm of length 1.5 μm. The amplitude of each arm being 1 μm and their speed being 1 μm/s, the swimmer evolves in an environment which Reynolds number is 6×10⁻⁶. The described swimmer has been simulated and its motion velocity toward one direction (straight line) is 10 nm/s.

Due to the change in shape of volumes 2c and 2d caused by light absorption (and in this time interval in which the couple 2c,2d changes shape absorbing light at the first radiation, the light absorption of couple 2a and 2b is substantially equal to zero, therefore there is a difference in absorption among volumes), the photonic structure 5 also changes shape. The change in shape of couple 2c and 2d is depicted in FIG. 3c where the change in shape of the photonic structure 5 is depicted schematically as a deformation of non-doped volume 4.

Due to the shape change of the photonic structure 5, the electromagnetic field at the first wavelength is not confined anymore in the portion of the swimmer containing the second couple 2c and 2d, but light at the first wavelength can propagate for the entire swimmer's body 10.

Therefore, if light at the first radiation is still shining on body 10, also the first couple formed by volumes 2a,2b can absorb light at the first radiation, and also the couple of volumes 2a,2b deform. This is depicted in FIG. 3d. However a new deformation of the swimmer's body causes a new deformation of the photonic structure 5 which again changes its resonant frequency. In this case the photonic structure's deformation prevents light at the first wavelength to propagate in the whole swimmer's body, limiting the light propagation within the portion of the body 10 including the first couple of volumes 2a,2b.

As depicted in FIG. 3e, the second couple of volumes thus relaxes and goes back to the non-contracted state, due to the fact that light at the first wavelength cannot propagate therein. This again causes a modification in the photonic structure 5 and light is now confined only within the non-doped volume 4, thus the swimmer goes back to the non-contracted state depicted in FIG. 3b and the cycle can be repeated.

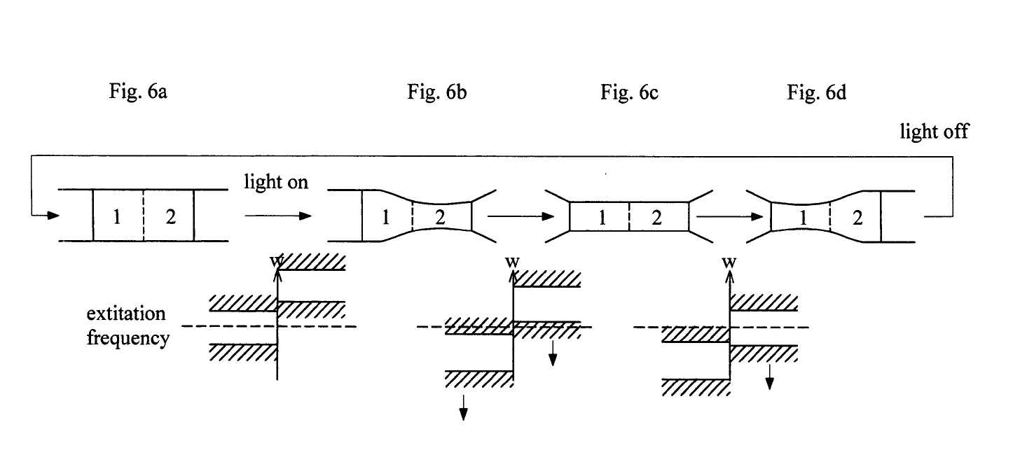

In FIGS. 6a-6d the mechanism of the photonic structure 5 acting in the swimmer 1 of FIGS. 3a-3e is described.

In the preferred embodiment, the photonic structure 5 is a photonic crystal formed by an array of scatterers (for example holes in the volume). Typically in photonic crystals, photonic band gaps, Bragg gaps, and so on (which make it possible to confine light in specific areas) is obtained using a lattice periodicity that is comparable to one half of the wavelength in the medium. This is essentially the Bragg's law: lambda/ne=2*a, where “a” is the periodicity, lambda is the wavelength of light in free space, and “ne” is the effective refractive index of the medium. Thus, suppose that the operative wavelength is at 630 nm, and the effective refractive index of the medium is 1.3, then, the lattice periodicity should be about 240 nm. Identically, the size of the scatterers should be large enough as to scatter light efficiently. In the case of holes drilled in the medium, a hole diameter of about 200 nm would be a reasonable choice.

The optimal operation of photonic structures depends on refractive indices, lattice (2D square or hexagonal, 3D simple cubic or face-centered cubic, etc. . . . ) and the type of scatterers. In general, the size of the scatterers is preferably between 0.1 and 5 times the wavelength in the medium (the wavelength in the medium is equal to the impinging wavelength divided by the material effective refractive index) and that the filling fraction of the scatterers is preferably between 1 and 70%.

Regarding the confinement mechanism, in FIGS. 6a-6d two photonic crystals with different periodicities (=filling fractions). Both of them have a small frequency range (omega) in which light transport is prohibited. Thus, light is only allowed when the excitation frequency lies out of the band gap. Step 1 of FIG. 6a: Light is turned on, the structure 1 (left) exhibits a band gap and structure 2 a conduction band. Light is therefore confined in structure 2, which contracts.

Step 2 of FIG. 6b: The contraction of structure 2 modifies the lattice and pushes the bands at lower frequencies. The proximity of the two structures also pushes the bands of structure 1 at lower frequencies, until the excitation frequency lies out of the band gap. Light therefore penetrates structure 1, which contracts.

Step 3 of FIG. 6c: The contraction of structure 2 makes such that the excitation frequency falls into the band gap. Structure 2 starts to expand.

Step 4 of FIG. 6d: light is turned off, and both structures go back to their initial form.

Instead of having two well-distinguished structures as above described, it might be more convenient to create a unique structure with a smooth gradient in the lattice parameter.

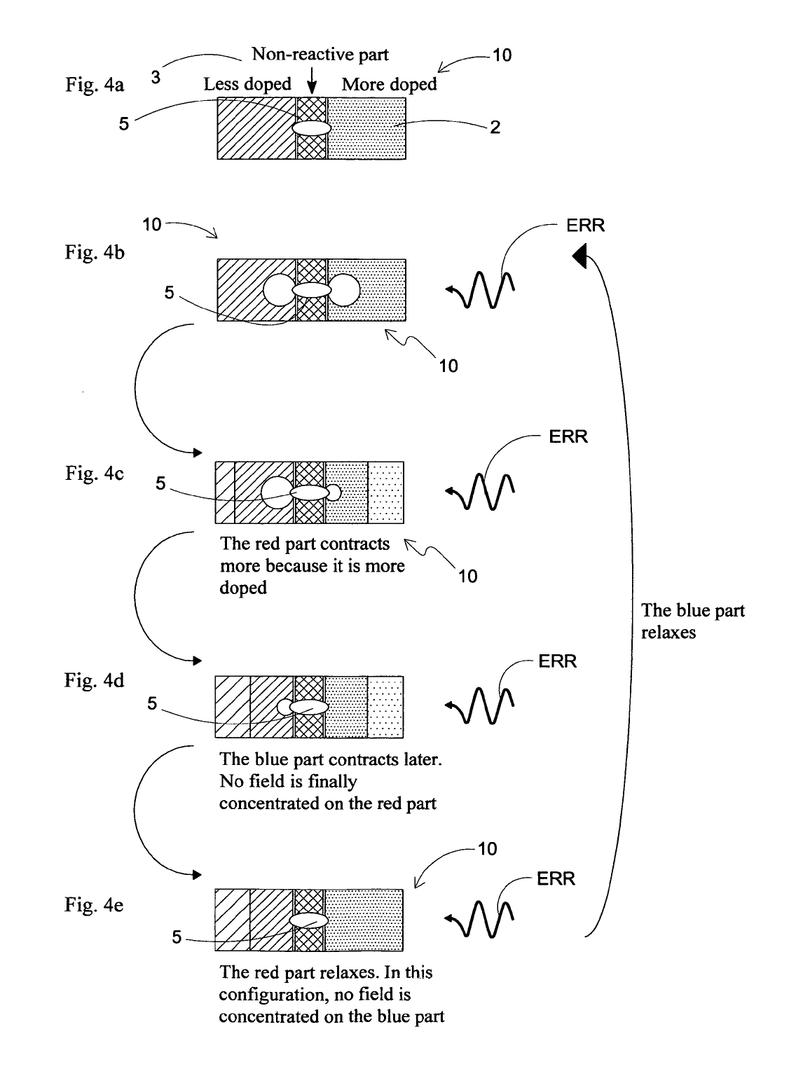

A general embodiment of the behavior of a photonic structure is depicted in FIGS. 4a-4e.

The body 10 includes two doped volumes 2, 3, separated by a non-doped volume 4 and a photonic structure 5 which in this case is present in both volumes 2,3 and in the non-doped volume 4. Both doped volumes are realized in a liquid crystal elastomer doped with a photoactive substance volume that absorbs a first electromagnetic radiation, such as for example a red radiation. The volumes are doped differently, i.e. the volume 2 is more doped than volume 3.

FIG. 4a depicts the body 10 of swimmer in a relaxed configuration. In the following steps, light at the first wavelength is always impinging the body 10.

In FIG. 4b light at the first wavelength is irradiated to the body 10 of swimmer 1. Initially, the disposition of the photonic structure 5 does not modify light absorption and light is absorbed by both volumes 2 and 3.

However, in the same time interval, more light is absorbed in the right volume 2 (i.e. the absorption of the first volume is different than the absorption in the second volume), due to a higher dye concentration, i.e. higher doping, of the volume 2 with respect to volume 3. A bigger contraction of the mostly doped volume 2 causes an asymmetric deformation of the photonic structure.

Due to the change in shape of volumes 2 and 3 caused by light absorption, the photonic structure 5 also changes shape. The change in shape of the photonic structure 5 is depicted in FIG. 4b. Due to the shape change of the photonic structure 5, the electromagnetic field at the first wavelength is not confined anymore equally in the two volumes 2,3 of the swimmer, but light at the first wavelength is more “confined” within the second volume 3.

This bigger confinement in volume 3 causes a bigger contraction of the same, which may result in contraction which is even bigger than the contraction of volume 2. This is the situation depicted in FIG. 4c, where due to this additional contraction, light results confined only in volume 3.

As depicted in FIG. 4d, the volume 2 thus relaxes and goes back to the non-contracted state, due to the fact that light at the first wavelength cannot propagate therein, due to the shape modification of the ophotonic structure 5. This again causes a modification in the photonic structure 5 and light is now confined in both volumes 2,3 thus the swimmer goes back to the non-contracted state depicted in FIG. 4b and the cycle can be repeated.

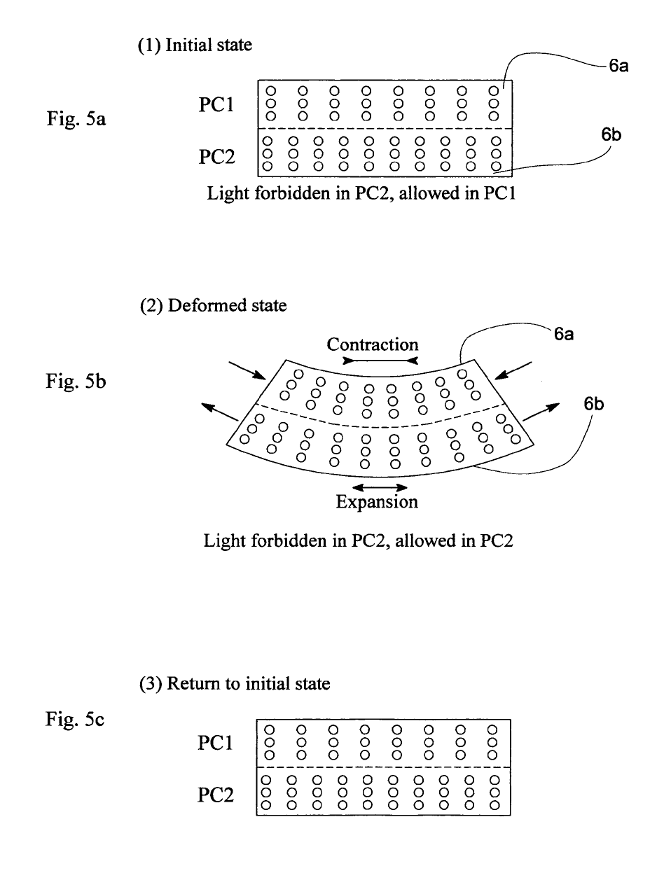

FIGS. 5a-5c represent a detail of a swimmer 1, such as the swimmer of FIGS. 3a-3e or 4a-4d which includes a photonic structure 5. The detail depicted is a portion of the photonic structure 5 in a preferred embodiment.

The photonic structure includes a two-layered first and second photonic crystal 6a and 6b stacked one on top of the other. In FIG. 5a the two photonic crystals 6a,6b are undeformed. The two photonic crystal patterns have different lattice constants and they are both realized in a slab of light-activated liquid-crystal elastomer, i.e. both layers in which the photonic crystals are realized includes the same dye which is activated by the same wavelength (first wavelength). In this initial state of FIG. 5a, at the wavelength of absorption of the dye, the lower most photonic crystal indicated with 6b exhibits a photonic band gap. Thus, light will only be confined to the region occupied by the photonic crystal 6a and a controlled deformation inn this region will occur, such as a contraction of the same, when light at the first wavelength impinges the structure 6a,6b. It is to be understood that the terms “topmost” and “lowermost” are used only for clarity purposes and in a descriptive manner with reference to the drawings, the orientation of the swimmer in space being arbitrary.

The material forming the volume in which the photonic crystal 6a will therefore come to the deformed state, as depicted in FIG. 5b. The deformation will induce a modification of the lattice constant of the two photonic crystals 6a and 6b, more precisely, a reduction of the lattice period for 6a and an increase of the lattice period for 6b. As a result, 6a could exhibit a photonic band gap (for instance, it becomes similar to 6b) and 6a could allow for light to propagate (it becomes similar to 6b). Light would then be confined only in the region occupied by 6b and the slab would go back to its initial state depicted in FIG. 5c.

This feedback mechanism would lead to an oscillatory behavior between the initial state and the deformed state without the need for a light intensity modulation, the period of an oscillation depending on the responsivity of the material.

### Preparation 1

General methods: Commercial reagents were used as received. All reactions were magnetically stirred and monitored by TLC on 0.25 mm silica gel plates (Merck F254) and column chromatography was carried out on Silica Gel 60 (32-63 μm). Yields refer to spectroscopically and analytically pure compounds. NMR spectra were recorded on a Varian Mercury-400, on a Varian Gemini 300 or on a Varian Gemini-200. Melting Point were recorded on a Electrothermal.

### 2-((E)-{4-[ethyl(6-hydroxyhexyl)amino]phenyl}diazenyl)-5-nitrobenzonitrile

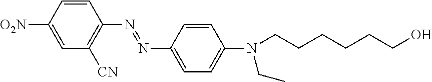 [SMILES: CCN(CCCCCCO)c1ccc(/N=N/c2ccc([N+](=O)[O-])cc2C#N)cc1]

2-Amino-5-nitrobenzonitrile (300 mg, 2.20 mmol) was dissolved in a solution of H₂O (3.7 ml), HCl (0.5 ml) and CH₃COOH (9.2 ml) and stirred at 60/70° C. overnight until complete dissolution. Then the solution was cooled to 0° C. and a cooled (0° C.) solution of NaNO₂ (127 mg, 1.84 mmol) in H₂O (2 ml) was added dropwise. Afterwards a solution of N-ethyl-N-(6-hydroxyhexyl)aniline (Jen et al. U.S. Pat. No. 7,601,849B1; 487 mg, 2.20 mmol) in MeOH (3.5 ml) was added dropwise. Addition of NaOH 2M until neutral pH and filtration of the precipitate afforded a crude product that was purified by FCC (Petroleum ether: Ethyl acetate=2:1). The desired product was obtain pure in 50% yield (435 mg, 1.10 mmol) as a purple solid. Mp=132° C. (dec); ¹H-NMR (300 MHz, CDCl₃) δ 8.59 (d, J=2.47 Hz, 1H, Ar), 8.40 (dd, J=9.06, 2.47 Hz, 1H, Ar), 7.97 (d, J=9.06, 3H, Ar), 6.72 (d, J=9.34 Hz, 2H, Ar), 3.67 (t, J=6.32 Hz, 2H, CH₂CH₂O), 3.52 (q, J=7.14 Hz, 2H, CH₃CH₂N), 3.42 (pt, J=7.69 Hz, 2H, CH₂CH₂N), 1.72-1.57 (m, 4H, CH₂CH₂O, CH₂CH₂N), 1.48-1.38 (m, 4H, CH₂CH₂CH₂O, CH₂CH₂CH₂N), 1.26 (t, J=7.14 Hz, 3H, CH₃CH₂N) ppm; ¹³C-NMR (50 MHz, CDCl3) δ 157.89, 152.83, 145.97, 143.87 (s, 5C, Ar), 129.06, 128.12 (d, Ar), 117.68 (d, 3C, Ar), 115.76 (s, CN), 111.70, 111.55 (d, Ar), 62.75 (t, CH₂CH₂O), 50.82 (t, CH₂CH₂N), 45.71 (t, CH₃CH₂N), 32.61 (t, CH₂CH₂O), 27.62 (t, CH₂CH₂N), 26.86, 25.62 (t, CH₂CH₂CH₂O, CH₂CH₂CH₂N), 12.51 (q, CH₃CH₂N) ppm.

### Preparation 2

### 6-[{4-[(E)-(2-cyano-4-nitrophenyl)diazenyl]phenyl}(ethyl)amino]hexyl acrylate (D6)

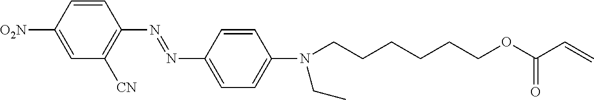 [SMILES: C=CC(=O)OCCCCCCN(CC)c1ccc(/N=N/c2ccc([N+](=O)[O-])cc2C#N)cc1]

To a solution of 2-((E)-{4-[ethyl(6-hydroxyhexyl)amino]phenyl}diazenyl)-5-nitrobenzonitrile (435 mg, 1.10 mmol) in dry DCM (38 ml), TEA (0.46 ml, 3.30 mmol) and acryloyl chloride (0.13 ml, 1.65 mmol) were added, then the mixture was stirred at rt for 2 h until a TLC (petroleum ether:ethyl acetate=2:1) showed the disappearance of the starting material (Rf=0.15) and the formation of a new product (Rf=0.73). The solution was washed with water (3×20 ml) and the combined organic layers dried over Na₂SO₄, filtered and evaporated under reduced pressure afforded a crude that was purified by FCC (petroleum ether:ethyl acetate=4:1) to give the desired product in 85% yield (420 mg, 0.94 mmol) as a purple solid. Mp=94-96° C.; ¹H-NMR (300 MHz, CDCl₃) δ 8.54 (d, J=2.47 Hz, 1H, Ar), 8.36 (dd, J=9.06, 2.47 Hz, 1H, Ar), 7.93 (dd, J=9.06, 2.47 Hz, 3H, Ar), 6.69 (d, J=9.34 Hz, 2H, Ar), 6.40 (dd, J=17.31, 1.37 Hz, 1H, CH═CH₂), 6.11 (dd, J=17.31, 10.16 Hz, 1H, CH═CH₂), 5.82 (dd, J=10.43, 1.37 Hz, 1H, CH═CH₂), 4.17 (t, J=6.59 Hz, 2H, CH₂CH₂O), 3.51 (q, J=7.14 Hz, 2H, NCH₂CH₃), 3.41 (pt, J=7.69 Hz, 2H, CH₂CH₂N), 1.69 (dt, J=13.74, 6.87 Hz, 4H, CH₂CH₂CH₂O, CH₂CH₂CH₂N) 1.50-1.42 (m, 4H, CH₂CH₂CH₂O, CH₂CH₂CH₂N), 1.26 (t, J=7.14 Hz, 3H, NCH₂CH₃) ppm; ¹³C-NMR (50 MHz, CDCl₃) δ 166.29 (s, C═O), 157.81, 152.78, 145.92, 143.83 (s, 5C, Ar), 130.66 (t, CH₂═CH), 129.02-128.09 (d, 4C, CH₂═CH, Ar), 117.65 (d, 2C, Ar), 115.74 (s, CN), 111.70, 111.55 (d, Ar), 64.33 (t, CH₂CH₂O), 50.78 (t, CH₂CH₂N), 45.72 (t, CH₃CH₂N), 28.56, 27.54 (t, CH₂CH₂CH₂O, CH₂CH₂CH₂N), 26.68, 25.81 (t, CH₂CH₂CH₂O, CH₂CH₂CH₂N), 12.49 (q, CH₃CH₂N) ppm.

Example of Realization of a swimmer 1.

A swimmer is made by filling (rising the temperature up to isotropic T of the mixture, around 100° C.) a mixture composed by 1.30% (w/w) D6, 18% (w/w) M1, 68.2% (w/w) M2, 1.50% (w/w) IN1 and 11% (w/w) 1,6 hexanedioldiacrylate, into a cell (40 um gap thickness) previously coated with Polyimide and rubbed.

A first increase of the temperature is made to reach the isotropic state (100 degrees), kept for half an hour, then cooling down to nematic phase of the mixture (around 40° C.) at a rate of 1 degree/minute. Polymerizing it by two photon absorption system (Nanoscribe©) in order to give it the desired shape.

The swimmer has a central body which is non-doped and four arms protruding from the same.

Body length: 100 μm,

### Body Thickness: 25 μm,

### Body Width: 40 μm

Arms diameter: 25 μm
Arm length: 75 μm

Dye is initially present everywhere in the structure, including the “non-doped body”, but inactivated by burning using a strong laser exposure during the fabrication step. The focused laser is shone at full power for a long time. Typically, using an objective 100×, NA 1.4, input beam is 30 mW, focus spot is 100 nm diameter, time of exposure: 1.5 ms/voxel.

The body and inside part of the legs will be inactivated. Only the external part of the legs is kept active.

In the front arms, the burning is a little bit longer (exposure time 3 ms/voxel) increasing the inactivation.

Bending in the front arms ranges from 5 to 35 degrees, bending in the back arms ranges from 0 to 15 degrees. At this wavelength, for a 1% dye doping, the absorption length is 5 um.

Wavelength of the impinging radiation onto the swimmer is equal to 532 nm, time modulated (I.e. ON/OFF at a frequency of 2 seconds). The mentioned radiation is sent in the same plane as the one of the swimmer.

The front arms open more and a bit faster than the back arms. The motion is anisotropic during the excitation and relaxation, thus creating the non-reciprocal motion. Non reciprocal motion can be also obtained by different speeds of the arms due to the fact that they reach their final position at different times. For example, arms that open at different speeds can produce a non-reciprocal motion if both arms reach their final position at different times (arm 1 is already steady at its final position, while arm 2 is still moving because it's slower; after that, they start moving together again, back to their initial position, so the movement is not reciprocal).

1. A liquid crystal elastomer actuator apt to move in a fluid, said actuator including a body having a dimension comprised between 100 nm and 800 μm so as to be considered a body having a low Reynolds number, said body comprising:
at least a first and a second spatially separated volumes, said first and said second volume of said body both comprising a liquid crystal elastomer, said first volume being doped with a first photoactive doping substance apt to absorb electromagnetic radiation at a first wavelength, and said second volume being doped with a second photoactive doping substance apt to absorb electromagnetic radiation at a second wavelength, and
said first and said second volumes being apt to change shape as a consequence of said light absorption at said first or second wavelength, so that in said body a first and a second joint are defined,
wherein a first absorbance of said first volume at a given wavelength is different than a second absorbance of said second volume at said given wavelength, said first and second absorbance being measured in the same time interval.

2. The actuator according to claim 1, wherein said first and said second wavelength are different one from the other and said given wavelength is either said first or said second wavelength.

3. The actuator according to claim 1, further including a photonic resonant structure, said photonic resonant structure being located within said body or at a distance from the same.

4. The actuator according to claim 3, wherein said photonic resonant structure is apt to modify light distribution within the actuator.

5. The actuator according to claim 3, wherein said photonic resonant structure is resonant at said first and/or said second wavelength and said given wavelength is either said first or said second wavelength.

6. The actuator according to claim 3, wherein said photonic resonant structure changes resonant wavelength as a consequence of said shape change due to light absorption by said first and/or said second volume.

7. The actuator according to claim 3, wherein said first and said second wavelength are substantially the same wavelength and said given wavelength is either said first or said second wavelength.

8. The actuator according to claim 3, wherein said photonic resonant structure includes a photonic crystal or a grating or a photonic antenna.

9. The actuator according to claim 1, wherein said Reynolds number is lower than 0.1.

10. The actuator according to claim 1, wherein said difference in said first and said second absorbance is due to laser burning of one of said first or second volume.

11. The actuator according to claim 1, wherein said body comprises a non-photoactive volume from which said first and second volumes protrudes.

12. The actuator according to claim 1, wherein said liquid crystal elastomer is uniaxial.

13. The actuator according to claim 1, wherein said liquid crystal elastomer is nematic.

14. The actuator according to claim 1, wherein said liquid crystal elastomer comprises at least one mesogenic aromatic molecule.

15. The actuator according to claim 14, wherein said at least one mesogenic aromatic molecule is selected from one or more compounds of a general formula (VI) 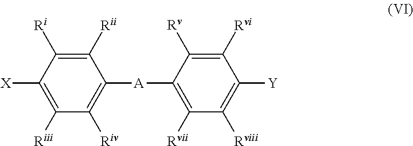
where the groups Rⁱ-R^{viii}, which can be the same or different are independently hydrogen; a halogen atom; nitro; amino; cyano; C₁-C₆ linear or branched alkyl chain, said chain optionally containing one or more double bonds, said chain optionally being substituted by one or more phenyl rings; a 5- or 6-members carbocyclic ring, optionally containing one or more heteroatoms selected from the group consisting of N, O and S, said ring optionally being aromatic;
A, which can also be absent, is a double bond-containing linker which can confer stiffness the compound (I), the linker is selected from the group consisting of a C₁-C₁₂ carbon chain, —N═N— and —CH═N—; the latter two being preferred;
X and Y, which can be the same or different, are NO₂ or organic weakly polar groups, preferably —OCH₃ or —CN.

16. The actuator according to claim 14, wherein said at least one mesogenic aromatic molecule is selected from the group consisting of

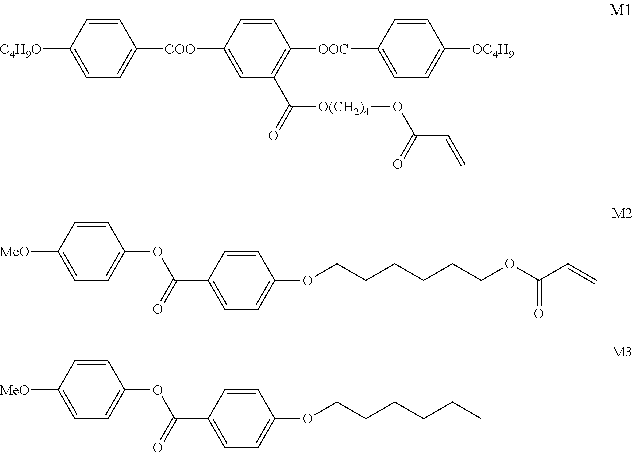

17. The actuator according to claim 1, wherein the photoactive doping substance is selected from the group consisting of

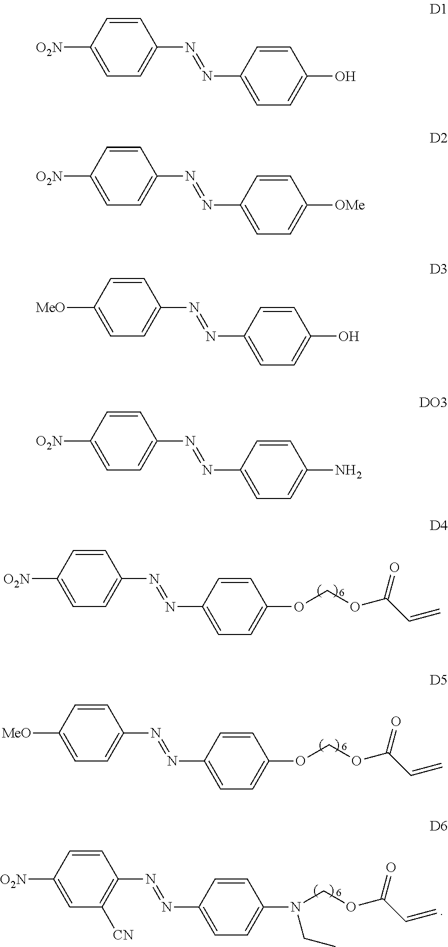

18. The actuator according to claim 1, wherein the liquid crystal molecules are 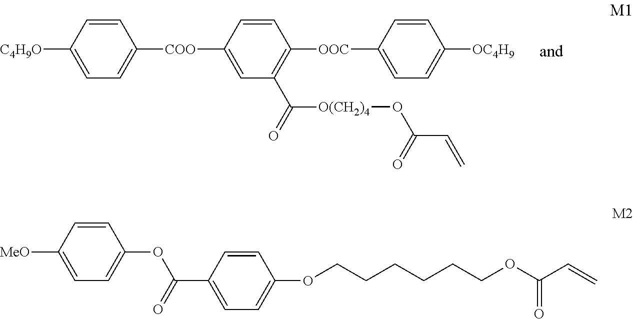
the photoactive doping substance is

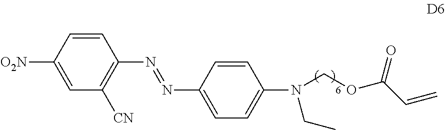

19. A method to move a body in a fluid at low Reynolds number, wherein said body has a dimension comprised between 100 nm and 800 μm and at least a first and a second spatially separated volumes, said first and said second volume of said body both comprising a liquid crystal elastomer, the method including the steps of:
doping said first volume with a first photoactive doping substance apt to absorb electromagnetic radiation at a first wavelength;
doping said second volume being doped with a second photoactive doping substance apt to absorb electromagnetic radiation at a second wavelength, Irradiating said body with electromagnetic radiation at said first wavelength, so as to cause a shape change in said first volume; and
irradiating said body with electromagnetic radiation at said second wavelength, so as to cause a shape change in said second volume;
wherein a first absorbance of said first volume at a given wavelength is different than a second absorbance of said second volume at said given wavelength, said first and second absorbance being measured in the same time interval.

20. The method according to claim 19, including:
modulating said irradiated electromagnetic radiation.

21. The method according to claim 19 or 20, including:
confining said irradiated electromagnetic radiation in a portion of said body by means of a photonic structure.

22. The method according to claim 20, wherein said confining depends on the body's shape.
